(19) United States
(12) Patent Application Publication
(10) Pub. No.: US 2016/0068691 A1
(43) Pub. Date: Mar. 10, 2016

(54) SILICON MATERIALS FROM THE PROCESSING OF LIQUID SILANES AND HETEROATOM ADDITIVES

(71) Applicant: NDSU RESEARCH FOUNDATION, Fargo, ND (US)

(72) Inventors: Philip Boudjouk, Fargo, ND (US); Justin Hoey, Fargo, ND (US); Guruvenket Srinivasan, Fargo, ND (US); Xuliang Dai, Fargo, ND (US); Kenneth Anderson, Fargo, ND (US); Matthew Frolich, Fargo, ND (US)

(73) Assignee: NDSU RESEARCH FOUNDATION, Fargo, ND (US)

(21) Appl. No.: 14/853,502

(22) Filed: Sep. 14, 2015

Related U.S. Application Data
(63) Continuation of application No. PCT/US2014/029789, filed on Mar. 14, 2014.
(60) Provisional application No. 61/794,678, filed on Mar. 15, 2013.

(51) Int. Cl. C09D 11/02; C08K 5/56; H01L 21/02; B05D 1/00; B05D 3/06; C08K 3/34; C08K 5/50

(52) U.S. Cl. CPC C09D 11/02; C08K 3/34; C08K 5/56; C08K 5/50; B05D 1/005; B05D 3/06; H01L 21/02123; H01L 21/02211; H01L 21/02282; H01L 21/02345

(57) ABSTRACT

Methods for forming silicon thin films and structures with incorporated metals, non-metals, and combinations thereof, liquid precursor compositions useful in such methods, and silicon thin films and structures with embedded heteroatom(s) are described. The compositions are generally liquid at ambient temperature and are comprised of liquid silane(s) and have metal and/or non-metal additives. Metal and non-metal sources include organometallic and organic compounds, respectively. The compositions may also contain a solvent. The compositions may be processed by printing, coating, or spraying onto a substrate and subjected to UV, thermal, IR, and/or laser treatment to form silicon films or structures with embedded heteroatom(s).

### CROSS-REFERENCE TO RELATED APPLICATIONS

This application is a 35 U.S.C. §111(a) continuation of PCT international application number PCT/US2014/029789 filed on Mar. 14, 2014, incorporated herein by reference in its entirety, which claims priority to, and the benefit of, U.S. provisional patent application Ser. No. 61/794,678 filed on Mar. 15, 2013, incorporated herein by reference in its entirety. Priority is claimed to each of the foregoing applications.

The above-referenced PCT international application was published as PCT International Publication No. WO 2014/145107 on Sep. 18, 2014, which publication is incorporated herein by reference in its entirety.

### STATEMENT REGARDING FEDERALLY SPONSORED RESEARCH OR DEVELOPMENT

This invention was made with Government support under DE-FG36-08G088160 awarded by the United States Department of Energy. The Government has certain rights in the invention.

### INCORPORATION-BY-REFERENCE OF COMPUTER PROGRAM APPENDIX

Not Applicable

### BACKGROUND OF THE INVENTION

1. Field of the Invention

This invention pertains generally to process schemes and methods for producing silicon based nanostructures and materials, and more particularly to compositions and methods for synthesis of silicon thin films and materials with embedded heteroatom(s).

2. Description of Related Art

Many energy related or semi-conductor based technologies rely on amorphous or microcrystalline silicon thin films and materials to act as the functional components in a device. To produce a usable device with the intended characteristics, numerous component materials with diverse optical, electrical, and physical properties are required. These material properties are commonly achieved through the introduction of heteroatom(s) into silicon materials. Depending on the function of the component silicon material, incorporation of a heteroatom(s) with silicon to obtain a specific material, e.g., doped, silicide, intermetallic, multi-phase, alloy or eutectic, may be desired.

Dopants are generally defined by their number of available outer electrons. Elements that have 3 valence electrons are used for p-type doping and elements with 5-valence electrons are used for n-doping. The most common dopants are boron to produce a p-type material and phosphorus for an n-type material although other heteroatoms have been successfully utilized.

Doping of amorphous or crystalline silicon film can be accomplished by a variety of methods such as magnetron sputtering, gaseous diffusion, and plasma enhanced chemical vapor deposition (PECVD).

In addition to doping amorphous and crystalline silicon, incorporation of heteroatoms with silicon to generate intermetallics, silicides, alloys, eutectics and multi-phase materials, may also influence the optical and electrical properties of the material.

Accordingly, there is a need for a process for introducing heteroatoms into silicon materials that is inexpensive, easy to perform, and produces consistent structures with functional properties. The present invention satisfies these needs as well as others and is an improvement in the art.

### BRIEF SUMMARY OF THE INVENTION

The present invention generally provides methods for forming silicon thin films and structures with incorporated inorganic, organic, organometallic materials, and combinations thereof, liquid precursor compositions useful in such methods, and silicon thin films and structures with embedded heteroatom(s).

The precursor ink compositions are generally liquid at ambient temperature and are comprised of liquid silane(s) and metal and/or non-metal additive(s). Metal and non-metal additives include inorganic, organic and organometallic compounds, respectively. The compositions may also contain a solvent. The ink compositions may be processed by printing, coating, or spraying onto a substrate and may be subjected to UV, thermal, IR, and/or laser treatment to form silicon films or structures with embedded heteroatom(s).

The precursor ink compositions that are used to produce thin films preferably have a silane base of at least one type of silane having the formula SiₓH_{y} where x is from 3 to 20, and y is 2x or (2x+2); an inorganic, organic, or organometallic additive and an optional solvent.

One metal additive source is a compound of the formula M⁽ⁿ⁾R_{z} where n is the oxidation state of the metal, z is equal to n, and R is independently H or an araalkyl, araalkenyl, araalkynyl group, an alkyl group, an alkenyl group, an alkynyl group, or any of the above groups containing an element from groups IIIA-VIIA.

Preferred non-metal or metalloid additive compositions are compounds of the formula ER₂, ER₃ or ER₄, where E is an element from group IIIA, IVA, VA or VIA except P, and each instance of R is independently H or an araalkyl, araalkenyl, araalkynyl group, an alkyl group, an alkenyl group, an alkynyl group, or any of the above groups containing an element from groups IIIA-VIIA.

Another additive component composition has the formula (RE)ₓM_{y}R_{z} where R is independently H or an araalkyl, araalkenyl, araalkynyl group, an alkyl group, an alkenyl group, an alkynyl group, or any of the above groups containing an element from groups IIIA-VIIA, E is an element from groups IIIA, IVA, VA or VIA, M is an element from groups IA-IVA, transition metal series and lanthanide series, x is 1-6, y is 1-6 and z is 0-6.

Another additive component composition has the formula (RE)xMyRz where R is independently H or an araalkyl, araalkenyl, araalkynyl group, an alkyl group, an alkenyl group, an alkynyl group, or any of the above groups containing an element from groups IIIA-VIIA, E is an element from groups IIIA, IVA, VA or VIA, M is an element from groups IA-IVA, transition metal series and lanthanide series, x is 0-6, y is 0-6 and z is 0-6.

The precursor ink formulations may be deposited on a substrate and processed to produce materials such as thin films, mixed phase materials, multi-phase materials, doped silicon materials, free-standing structures, silicides, intermetallics, alloys, eutectics, nanoparticle/nanostructure embedded materials and heteroatom embedded materials.

According to one aspect of the invention a precursor ink composition is provided containing cyclic silanes, polyhydrosilanes or similar materials and at least one inorganic, organic or organometallic additive.

Another aspect of the invention is to provide a process for producing silicon or silicide compositions that includes the transformation of a precursor ink with heat treatments and light irradiation.

Another aspect of the invention is to provide a process that uses electromagnetic irradiation and/or conventional thermal treatment to transform the silane containing composition to solid silicon containing material prior, in-situ, or post deposition.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic flow diagram of one process for forming silicon nanostructures according to one embodiment of the invention.

FIG. 2A is a graph of Raman spectroscopy results of degenerately doped n-Si and p-Si thin films as-deposited (Org-P is PBn₃, Org-B is BBn₃).

FIG. 2B is a graph of Raman spectroscopy of degenerately doped n-Si and p-Si thin films after laser annealing (Org-P is PBn₃, Org-B is BBn₃).

FIG. 3 is a graph of the resultant resistivity values for the films vs. the atomic doping concentration of phosphorus for spin-coated silicon films from Si₆H₁₂ doped with PBn₃ and laser crystallized at 700, 850 and 1000 mW.

### DETAILED DESCRIPTION OF THE INVENTION

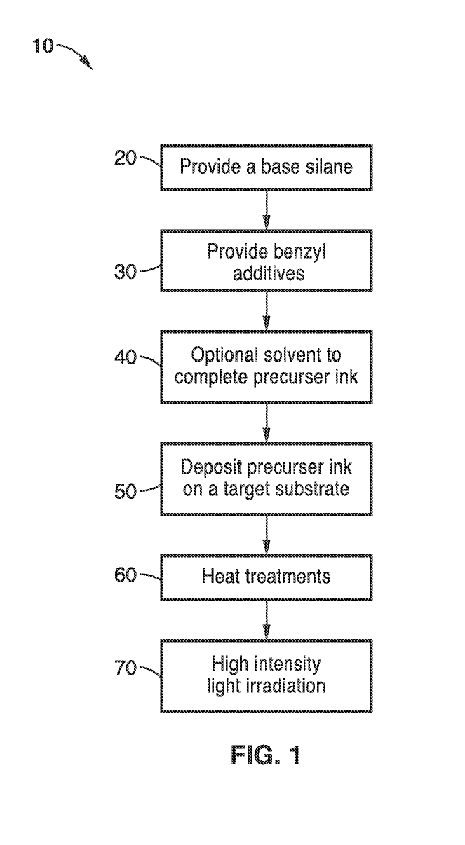

Referring more specifically to the drawings, for illustrative purposes an embodiment of the method for forming silicon thin films with embedded heteroatoms and precursor ink compositions of the present invention is described and depicted generally in FIG. 1. It will be appreciated that the methods may vary as to the specific steps and sequence and the ink compositions may vary as to elements without departing from the basic concepts as disclosed herein. The method steps are merely exemplary of the order in which these steps may occur. The steps may occur in any order that is desired, such that it still performs the goals of the claimed invention.

Turning now to FIG. 1, a flow diagram of one embodiment of method 10 for generating doped silicon films from a precursor ink containing silane and an additive is shown. Generally, the method 10 begins with the selection of a base silane that can be deposited and processed to form silicon thin films and structures with embedded heteroatoms. The ink compositions are normally liquid at ambient temperature and are comprised of liquid silane(s) and metal and/or non-metal additives with optional solvent. Metal and non-metal additives include inorganic, organic, and organometallic compounds.

At block 20, a silane compound of formula, SiₓH_{y} where x is from 3 to 20, and y is 2x or (2x+2) is selected. Liquid cyclic silanes of formula SiₙH₂ₙ such as cyclohexasilane (Si₆H₁₂) or cyclopentasilane, (Si₅H₁₀), silylcyclopentasilane, (Si₆H₁₂), and linear or branched silanes of formula SiₙH₂ₙ₊₂ such as trisilane, (Si₃H₈), tetrasilane, (Si₄H₁₀), neo-pentasilane, (Si₅H₁₂), and polyhydrosilanes are particularly preferred as a base silane. Solvents may optionally be included in block 20.

Additives are selected and prepared at block 30 of FIG. 1 to be combined with the silane base provided at block 20. A wide variety of metal and non-metal additive compositions can qualify. Additive compositions can be used alone or in combination with solvent(s) and/or one or more other additive compositions.

Preferred metal additive compositions are compounds of the formula M⁽ⁿ⁾R_{z} where n is the oxidation state of the metal M, z is equal to n, and R is at least one organic group. In one embodiment, R is an araalkyl group such as benzyl or naphthylmethyl in which there is a methylene linkage to the metal M. In another embodiment, the R is an alkyl group such as linear, branched, or cyclic saturated hydrocarbons. In another embodiment, R is an alkenyl group such as linear, branched, or cyclic unsaturated hydrocarbons. In another embodiment, R is an alkynyl group. In a further embodiment, R is an aryl group such as phenyl, naphthyl, or polycylic aromatic hydrocarbon.

A non-metal additive to the ink may be a non-metal or metalloid containing compound of formula ER₃ where E is an element from group IIIA and each instance of R is independently H, benzyl, n-butyl, t-butyl, isopropyl, or other substituted aromatic but at least one instance of R is benzyl, n-butyl, t-butyl, isopropyl, or other substituted aromatic.

Another suitable component is a non-metal or metalloid containing compound of formula ER₃ where E is an element from group IIIA and each instance of R is independently H, benzyl or naphthylmethyl but at least one instance of R is benzyl or naphthylmethyl.

A further component is a non-metal or metalloid containing compound of formula ER₄ where E is an element from group IVA and each instance of R is independently H, benzyl, t-butyl, n-butyl, isopropyl, or other substituted aromatic but at least one instance of R is benzyl, t-butyl, n-butyl, isopropyl, or other substituted aromatic.

Another preferred component is a non-metal or metalloid containing compound of formula ER₃ where E is an element from group VA and each instance of R is independently H, benzyl, n-butyl, isopropyl, or other substituted aromatic but at least one instance of R is benzyl, n-butyl, isopropyl, or other substituted aromatic.

In one embodiment, the component has the formula BiR₃ where each instance of R is independently H, benzyl, t-butyl, n-butyl, isopropyl, or other substituted aromatic but at least one instance of R is benzyl, t-butyl, n-butyl, isopropyl, or other substituted aromatic.

Another suitable component is a non-metal or metalloid containing compound of formula ER₂ where E is an element from group VIA and each instance of R is independently H, benzyl, t-butyl, n-butyl, isopropyl, or other substituted aromatic but at least one instance of R is benzyl, t-butyl, n-butyl, isopropyl, or other substituted aromatic.

Another component may be of the formula (RE)ₓM_{y}R_{z} where R is independently H or an araalkyl, araalkenyl, araalkynyl group, an alkyl group, an alkenyl group, an alkynyl group, or any of the above groups containing an element from groups IIIA-VIIA, E is an element from groups IIIA, IVA, VA or VIA, M is an element from groups IA-IVA, transition metal series and lanthanide series, x is 0-6, y is 0-6 and z is 0-6.

Optionally, the precursor ink is a combination of a silane and an additive which can also include a solvent provided at block 40 of FIG. 1. Preferred solvents include cyclooctane and toluene. The selection of the solvent will be influenced by the selection of the silane and additive for the final precursor ink composition. The quantity of solvent used to complete the ink composition in these embodiments can be optimized to produce a final ink composition. The selection and amount of optional solvents in the ink compositions can also be optimized for the type of ink deposition scheme that is selected at block 50.

Optionally, the precursor ink in block 40 may be heated or UV irradiated to provide a more suitable precursor before deposition in block 50.

The final precursor ink of a combination of base silanes, additives and optional solvents can be used to form thin films and other structures. At block 50, the ink may be deposited on a substrate using a variety of available techniques. For example, precursor inks can be deposited by spin-coating, liquid phase deposition (LPD); spray pyrolysis deposition; chemical vapor deposition (CVD); and immersion techniques. In one example, heat and/or UV irradiation is provided during and/or after the deposition.

Once the precursor ink has been deposited on the desired substrate at block 50, the deposited material may be subjected to one or more heat treatments at block 60 of FIG. 1. The temperature and duration of each heat treatment may vary depending on the composition of the precursor ink, deposited material thickness, and desired characteristics of the final material.

The heat treatment of the deposited films can be a single exposure to a single temperature for a set duration. The treatment may also be a first exposure at one temperature for a period and then a second exposure at a second temperature for a second period. Typical heat treatments have temperatures ranging from approximately 150° C. to approximately 1200° C. at times from 1 minute to approximately 4 hours.

Generally, the thermal treatments lead to the progressive transformation of the doped liquid silane inks into polysilane, amorphous silicon and then to crystalline silicon with the additional irradiation from high intensity light at block 70 of FIG. 1. Accordingly, the process can end with the heat treatments of block 60 when the final film of doped amorphous silicon is the desired end material. However, further processing of the heat treated film with intense UV, IR, and/or laser light will form crystalline silicon films or structures with embedded heteroatoms.

The preferred source of radiation at block 70 is a laser. The wavelength, power and duration of illumination of the film by the laser treatments can be optimized, accounting for ink composition, material thickness and the desired material morphology. Laser wavelengths can range from 190 nm to 1100 nm, with time scale from approximately 1 nm, to 1 second. Average laser energy density is approximately 5 to 30 mJ/cm² or an average power density of approximately 250 to 1500 W/cm².

The invention may be better understood with reference to the accompanying examples, which are intended for purposes of illustration only and should not be construed as in any sense limiting the scope of the present invention as defined in the claims appended hereto.

### Example 1

To demonstrate the variety of additives that can be used with the base silane composition to generate precursor inks BBn₃, PBn₃, AsBn₃, SbBn₃, BiBn₃, ZrBn₄, SnBn₄, Bi(SBn)₃, Pb(SBn)₂, and (Bn₂SnS)₃ compounds where Bn=PhCH₂ were produced and evaluated as precursor inks.

The benzylated compounds were synthesized according to the following reaction scheme, where M=B, P, As, Sb, Bi:

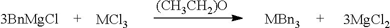

The benzylated compounds were synthesized according to the following reaction scheme, where M=Zr, Sn:

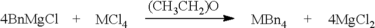

The Bi(SBn)₃ compound was synthesized according to the following reaction scheme:

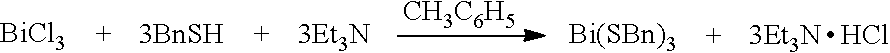

The Pb(SBn)₂ compound was synthesized according to the following reaction scheme:

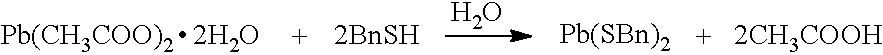

The (Bn₂SnS)₃ compound was synthesized according to the following reaction scheme:

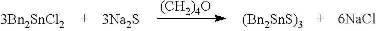

The products were characterized by NMR, FTIR and melting points.

### Example 2

In order to demonstrate the precursor ink aspects of the invention, different inks were synthesized and evaluated for use in producing doped silicon thin films. The first was an ink for producing an antimony (Sb) containing composite material generated by reaction of a Sb(CH₂Ph)₃ compound.

The reaction of Sb(CH₂Ph)₃ with a silane (Si₆H₁₂) in a solvent medium was found to produce a mixture of which a black solid precipitated. However, the reaction of Sb(CH₂Ph)₃ with Si₆H₁₂ (Sb:Si ratio of ˜1:100) in the absence of a solvent produced a homogenous solution. When a mixture of Sb(CH₂Ph)₃ and Si₆H₁₂ (Sb:Si ratio of ˜1:100) was heated at 100° C. for 10 minutes, a black solid formed. When the reaction was heated at 60° C., the solution turned to brown over a period of several minutes and a dark brown solution was obtained after heating for 1.5 hours. The resulting liquid was characterized by NMR spectroscopy after diluting with C₆D₆, and the spectra indicated that all benzyl-groups reacted and converted into toluene. Although polysilane was evident by NMR analysis, the resultant liquid was well-soluble in toluene and therefore was potentially useful for spin-coating.

Since phosphorus is smaller than antimony and thus maintains a higher solid-state diffusion, the second ink evaluated included the P analog, P(CH₂Ph)₃. The P(CH₂Ph)₃ maintained the trend demonstrated for Sb(CH₂Ph)₃ as follows. When a mixture of P(CH₂Ph)₃ and Si₆H₁₂ (with P:Si≈1:100) was heated at 60° C. for 3 hours, less than ˜5% of the benzyl-groups were converted into toluene. And even though some polysilane was formed, the resultant liquid was mostly soluble in C₆D₆ where, again, no new phosphorus species were detected by NMR spectroscopy, other than P(CH₂Ph)₃. If a similar mixture was heated to 100° C. for 7 minutes, a viscous gel was formed which could be only partially dissolved in C₆D₆. Of the components dissolved in C₆D₆, no new phosphorus species were detected by NMR analysis. It is worthwhile to mention that a similar viscous gel was obtained if the heating time (at 100° C.) was reduced to 3 minutes. Samples for spin-coating were prepared by heating a similar mixture, heated at 100° C. for only 2 minutes and the resulting viscous liquid was soluble in toluene.

### Example 3

To further demonstrate the methods, several of the ink precursors, such as those described in Example 2, were utilized in the formation of thin films via spin coating. The spin coated thin films were subjected to post-deposition processing that included pyrolysis on a hot plate inside the glovebox as well as additional treatment with a laser. These treatments led to progressive transformation of the coated liquid silane inks into polysilane, amorphous silicon, and, finally, crystalline silicon.

Inks amenable to spin coating were formulated by mixing Si₆H₁₂ with cyclooctane or toluene to give 10 vol. % solutions. Additive was introduced to give a Si:M or Si:E additive atom ratio of approximately 100:1. Such inks were dispensed onto quartz substrates while spinning (1500 rpm) and concurrently irradiated with ˜4 mW/cm² UV light (λ<400 nm) emitted from a filtered 500 Watt Hg(Xe) arc lamp source. The spin-coated samples were subsequently heat treated at 100° C. for 10 minutes to remove the solvent and then at 400° C. for 1 hour to give amorphous silicon films.

Prior to laser treatment, films were placed in a tube furnace or hotplate and annealed at 550° C. for 1 hour in a nitrogen atmosphere to reduce the amount of hydrogen in the film. Those samples were then laser crystallized using a pulsed 355 nm laser with 0.2-0.8 W power, a scan speed of 25 mm/sec and a scanning overlap such that the sample was treated six times in total. Some samples were annealed at 800° C. for 1 hour in a nitrogen atmosphere in a tube furnace.

After all treatments, aluminum contacts were sputtered onto the samples to give channel widths of ˜2600 μm and lengths of ˜175 μm. I-V measurements were taken using an Agilent B1500A semiconductor analyzer. Actual resistances were taken at a 10 V potential across the pads. Film thickness was measured by ablating a trench in the sample with the HIPPO laser using a 10 μm beam spot. The ablation was self-limiting at the quartz substrate which did not absorb the laser energy. The ablated trench was then measured by contact profilometry to give film thickness.

The overall approach for fabricating and testing these thin films used the following steps. Step 1: Preparation of inks; Step 2: Spin-coating with UV irradiation; Step 3: Hotplate at 100° C. and 400° C.; Step 4: Tube furnace 550° C. to 1500° C.; Step 5: Laser crystallization, and trenching; Step 6: 4-point probe measurements; Step 7: Sputter Al contacts; Step 8: Resistance/geometry measurements; and Step 9: Film thickness measurements from ellipsometry and profilometry.

The results of the thin film evaluations are compiled in Table 1. The lowest resistivities were observed for films that were subjected to laser recrystallization and, in particular, the lowest resistivity value of 3.6×10⁻³ Ω·cm for the film prepared with PBn₃. With the additive SbBn₃, a resistivity of 3.3×10⁻² Ω·cm was observed. Finally, ink with additive BBn₃ resulted in a resistivity as low as 1.1×10⁻² Ω·cm.

### Example 4

To further demonstrate the characteristics of doped thin films generated by precursor inks, a diode test structure for n-type spin-coated silicon films was produced. To confirm the ability to use these films for PV applications, the ability to form a p-n junction is critical. Therefore, diodes utilizing p-type silicon wafers and n-type films were fabricated for evaluation.

Generally, the diodes were composed of p-type Si wafers with a 250 nm Al bottom electrode and a 60 nm n-type silicon layer and top electrode. Specifically, the substrates were silicon wafers with 1-10 Ω·cm conductivity, doped with boron, ˜525 μm thick, double-side polished <110> orientation. Before spin-coating, the wafers were RCA cleaned to remove any organics and oxides present on the wafer. A 10 vol. % solution of Si₆H₁₂ in cyclooctane was prepared to which PBn₃ additive was introduced to obtain a Si:P ratio of approximately 1000:1. The precursor ink was spin-coated onto the doped silicon wafer at 1200 rpm with simultaneous UV exposure. The samples were promptly placed on a 100° C. preheated hotplate for 10 minutes, followed by a ramp to 400° C. and thermal soak for 1 hour. The samples were then placed in an N₂ atmosphere tube furnace and annealed at 550° C. for 2 hours. After heat treatment the samples were laser crystallized using a 355 nm pulsed laser with an elliptical beam approximately 10 μm by 500 μm. Aluminum was sputtered onto the n-type film and patterned using photolithography and a lift-off method to produce a top electrode. After device completion, the samples were annealed in nitrogen at 200° C. for one hour to reduce the contact resistance between the metals and the silicon.

I-V data were obtained using an Agilent B1500A semiconductor analyzer with a voltage sweep from −10V to 10V, with a maximum current of 100 mA. For example, I-V data for n-type spin-coated film diodes with laser treatments of 150, 175, 200 and 225 mW power were obtained. The results indicate that diodes are functional at laser powers up to 200 mW, above which, the diode becomes non-operational. Reverse breakdown voltage was above 10 V.

### Example 5

Both p- and n-type silicon films were deposited using aerosol assisted atmospheric pressure chemical vapor deposition (AA-APCVD) of precursor inks. Precursor inks containing a liquid silane, additive, and solvent were fed into an ultrasonic atomizer, subsequently vaporized and transported to a substrate with an inert carrier gas through a flow channel. The gas was then dispensed over a substrate heated to temperatures of approximately 450 to 500° C. Films approximately 100 nm thick were deposited and further treated with laser crystallization. Resistivities of the films are shown in Table 2. The doped p-Si films generated using the precursor inks showed a significant decrease in resistivity after laser annealing. This confirmed that the heteroatom elements incorporated in the film can be activated by laser annealing.

To evaluate the effects of laser annealing, p-Si films were generated by deposition of an ink containing cyclohexasilane and tribenzyl boron as an additive. The resistivities of as-deposited thin films were compared to those of thin films after laser annealing. XRF analyses of these films showed the presence of boron in the doped film. As an example, the resistivity of a degenerately doped p-Si thin film deposited on a substrate at 450° C. was 1×10⁶ Ω·cm and after laser annealing was ˜10 Ω·cm.

By comparison, n-type films generated using precursor inks containing cyclohexasilane and additive PBn₃ followed a similar trend. XRF analyses of as-deposited and laser annealed films showed presence of P in the film. Reductions in resistivities were obtained after thermal or laser annealing.

It was observed that higher substrate temperature and laser annealing are important in obtaining low resistivity in Si thin films generated by AA-APCVD. In comparison to the p-type Si films, the resistivities of n-type Si thin films using precursor inks with PBn₃ additive at 450° C. was 1×10⁶ Ω·cm, as deposited and 1.6 Ω·cm after laser annealing. Similarly, the resistivities of n-type Si thin films at 500° C. were 1×10⁴ Ω·cm as deposited and 0.1 Ω·cm after laser annealing.

Accordingly, laser annealing/crystallization assists in the activation and incorporation of the additive elements in the Si thin films.

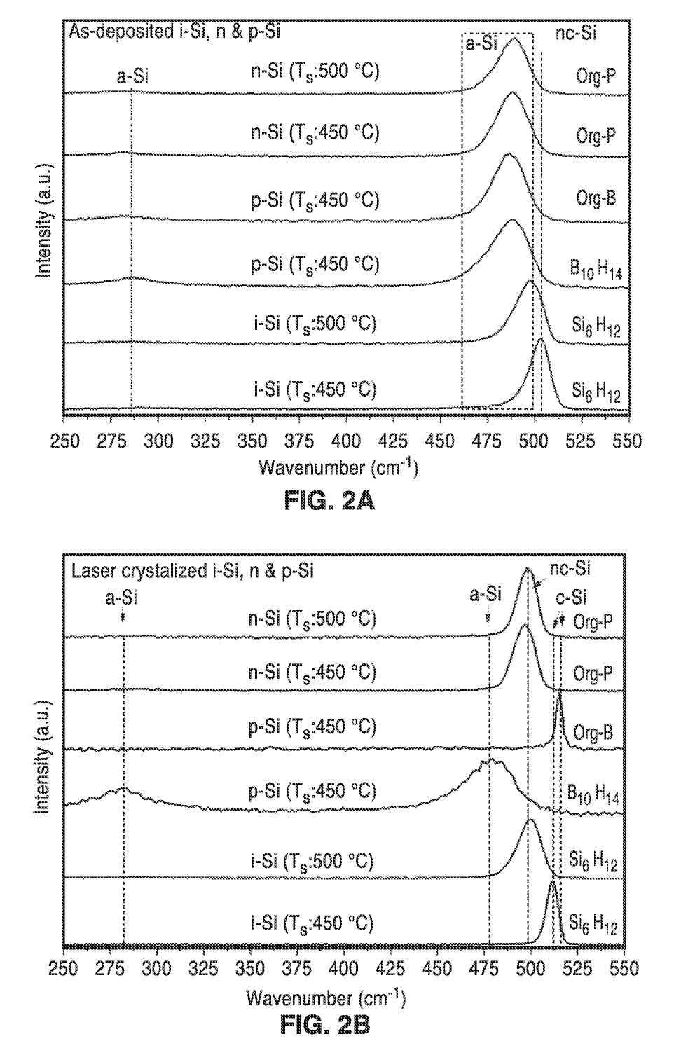

To further demonstrate the structural changes caused by laser annealing, as deposited films and laser annealed, films were evaluated using Raman spectroscopy. As-deposited and laser annealed films were evaluated and are presented in FIG. 2A and FIG. 2B. Except for intrinsic silicon films (i-Si), all the doped as-deposited Si films displayed a characteristic broad peak centered at 480 cm⁻¹ corresponding to an amorphous Si phase as shown in FIG. 2A. Other doped films showed a shift in the peak to higher wavenumbers of 500 cm⁻¹, depicting the presence of mixed a-Si:H and nanocrystalline Si phase in the films as seen in FIG. 2B. These observations demonstrate that all additive molecules do not incorporate in the same way with Si₆H₁₂.

### Example 6

Heteroatom concentrations within the spin-coated Si films were evaluated to further illustrate the characteristics of films generated from precursor inks with PBn₃ additive. In this illustration, a 0.75 atomic % P to Si ink with additive PBn₃ and Si₆H₁₂ at 10 vol. % in toluene was spin-coated onto a RCA cleaned 1-10 Ω·cm B-doped silicon wafer. Immediately before and during spin-coating, the sample was UV irradiated with a high pressure xenon enhanced mercury vapor arc lamp at ˜4 mW/cm². After deposition, the sample was subjected to a heat treatment at 100° C. for 10 minutes followed by 400° C. for 1 hour. All processing was done inside an inert atmosphere glovebox of N₂ with oxygen content below 1 ppm. After heat treatment, the sample was laser crystallized using a UV pulsed laser. Analysis from Secondary Ion Mass Spectroscopy (SIMS) showed phosphorus concentration was approximately 2×10²⁰ atoms/cm³ or 0.4 atomic %, which is near that of the precursor ink prior to processing. This shows that PBn₃ is an efficient carrier for the introduction of P in the silicon films.

The concentration of phosphorus in the spin-coated silicon film precursor ink was varied from approximately 0.0001 atomic % to 0.75 atomic % to determine the dependence of film resistivity on the dopant level. After processing and heat treatment, the samples were laser crystallized using a pulsed 355 nm UV laser. The laser beam had an elliptical shape of size 10 μm by approximately 700 μm and was rastered across the sample at 25 mm/sec with a pulse repetition of 50 kHz, and horizontal beam shift of 50 μm. Average laser power was 700 mW, 850 mW, and 1000 mW.

After crystallization, sheet resistance of the samples was measured using a 4-point probe. Film thickness was measured using ellipsometry, where average thickness was found to be from 40 nm to 80 nm. The resultant resistivity values for the films vs. the atomic doping concentration of phosphorus were evaluated.

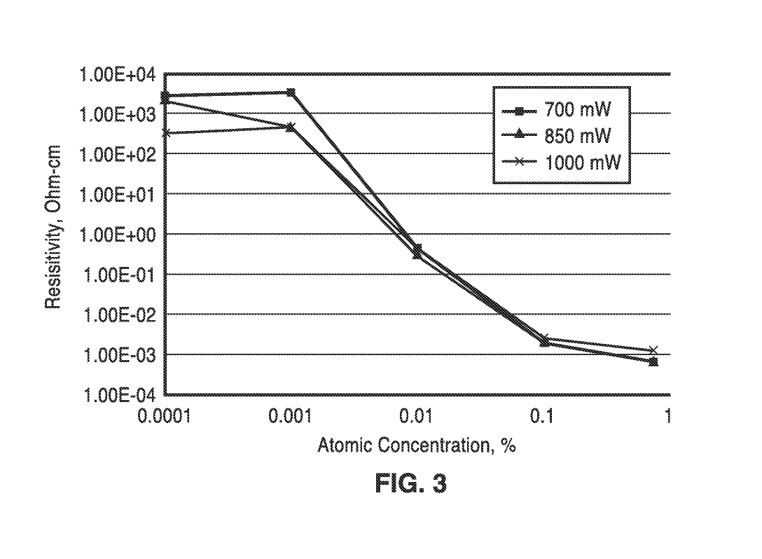

The resistivity vs. precursor ink P concentration for spin-coated films laser crystallized at 700, 850 and 1000 mW is shown in FIG. 3. Here it is evident that resistivities generally increase with a decrease in doping concentration. These results confirm that the resistivity and doping level can be successfully controlled from 0.0001 atomic % to 0.75 atomic %.

From the discussion above it will be appreciated that the invention can be embodied in various ways, including but not limited to the following:

1. A precursor composition for synthesizing silicon thin films and structures with embedded heteroatom(s), comprising: (a) a liquid silane; and (b) at least one benzyl additive with one or more heteroatoms.

2. A composition as recited in any previous embodiment, wherein the additive is selected from the group of additives consisting of BBn₃, PBn₃, AsBn₃, SbBn₃, BiBn₃, ZrBn₄, SnBn₄, Bi(SBn)₃, Pb(SBn)₂, and (Bn₂SnS)₃ compounds where Bn=PhCH₂.

3. A composition as recited in any previous embodiment, wherein the benzyl additive is a compound of the formula M⁽ⁿ⁾R_{z} where n is the oxidation state of the metal M, z is equal to n, and R is at least one organic group.

4. A composition as recited in any previous embodiment, wherein the R group is an araalkyl group in which there is a methylene linkage to the metal M.

5. A composition as recited in any previous embodiment, wherein the R group is selected from the group: a linear, branched, or cyclic saturated alkyl group; a linear, branched, or cyclic unsaturated alkenyl group; an alkynyl group an aryl group or a hydrogen atom.

6. A composition as recited in any previous embodiment, wherein the benzyl additive is a non-metal or metalloid containing compound of the formula ER₃ where E is an element from periodic table group IIIA and each instance of R is independently selected from the group H, benzyl, n-butyl, t-butyl, isopropyl substituted aromatic hydrocarbon and at least one instance of R is a benzyl, n-butyl, t-butyl, isopropyl group.

7. A composition as recited in any previous embodiment, wherein the benzyl additive is a non-metal or metalloid containing compound of the formula ER₃ where E is an element from periodic table group IIIA and each instance of R is independently selected from the group H, benzyl or naphthylmethyl and at least one instance of R is a benzyl or naphthylmethyl group.

8. A composition as recited in any previous embodiment, wherein the benzyl additive is a non-metal or metalloid containing compound of the formula ER₃ where E is an element from periodic table group VA and each instance of R is independently selected from the group H, benzyl, n-butyl, isopropyl, and at least one instance of R is a benzyl, n-butyl or isopropyl group.

9. A composition as recited in any previous embodiment, wherein the benzyl additive is a non-metal or metalloid containing compound of the formula ER₄ where E is an element from periodic table group IVA and each instance of R is independently selected from the group H, benzyl, t-butyl, n-butyl, isopropyl and at least one instance of R is a benzyl, t-butyl, n-butyl, or isopropyl group.

10. A composition as recited in any previous embodiment, wherein the benzyl additive is a non-metal or metalloid containing compound of the formula ER₂ where E is an element from periodic table group IVA and each instance of R is independently selected from the group H, benzyl, t-butyl, n-butyl, isopropyl, or other substituted aromatic and at least one instance of R is a benzyl, t-butyl, n-butyl, or isopropyl group.

11. A composition as recited in any previous embodiment, wherein the benzyl additive is a compound of the formula BiR₃ where each instance of R is independently selected from the group H, benzyl, t-butyl, n-butyl, isopropyl, and at least one instance of R is a benzyl, t-butyl, n-butyl or isopropyl group.

12. A composition as recited in any previous embodiment, wherein the benzyl additive is a compound of the formula (RE)ₓM_{y}R_{z} where R is independently selected from the group H, an araalkyl group, an araalkenyl group, an araalkynyl group, an alkyl group, an alkenyl group, an alkynyl group, E is an element from groups IIIA, IVA, VA or VIA and M is an element selected from the group of periodic table groups IA-IVA, transition metal series and lanthanide series, x is 0-6, y is 0-6 and z is 0-6.

13. A composition as recited in any previous embodiment, wherein the R group is an araalkyl group, an araalkenyl group, an araalkynyl group, an alkyl group, an alkenyl group, an alkynyl group containing an element from periodic table groups IIIA-VIIA.

14. A precursor composition for synthesizing silicon thin films and structures with embedded heteroatom(s), comprising: (a) a liquid silane of the formula SiₙH₂ₙ or SiₙH₂ₙ₊₂ where n is from 3 to 20; (b) at least one benzyl additive; and (c) at least one solvent.

15. A composition as recited in any previous embodiment, wherein the solvent selected from the group of solvents consisting of toluene, xylene, cyclooctane, 1,2,4-trichlorobenzene, dichloromethane and mixtures thereof.

16. A composition as recited in any previous embodiment, wherein the additive is selected from the group of additives consisting of BBn₃, PBn₃, AsBn₃, SbBn₃, BiBn₃, ZrBn₄, SnBn₄, Bi(SBn)₃, Pb(SBn)₂, and (Bn₂SnS)₃ compounds where Bn=PhCH₂.

17. A composition as recited in any previous embodiment, wherein the benzyl additive is a compound of the formula M⁽ⁿ⁾R_{z} where n is the oxidation state of the metal M, z is equal to n, and R is at least one organic group.

18. A composition as recited in any previous embodiment, wherein the R group is an araalkyl group in which there is a methylene linkage to the metal M.

19. A composition as recited in any previous embodiment, wherein the R group is selected from the group: a linear, branched, or cyclic saturated alkyl group; a linear, branched, or cyclic unsaturated alkenyl group; an alkynyl group an aryl group or a hydrogen atom.

20. A composition as recited in any previous embodiment, wherein the benzyl additive is a non-metal or metalloid containing compound of the formula ER₃ where E is an element from periodic table group IIIA and each instance of R is independently selected from the group H, benzyl, n-butyl, t-butyl, isopropyl substituted aromatic hydrocarbon and at least one instance of R is a benzyl, n-butyl, t-butyl, isopropyl group.

21. A composition as recited in any previous embodiment, wherein the benzyl additive is a non-metal or metalloid containing compound of the formula ER₃ where E is an element from periodic table group IIIA and each instance of R is independently selected from the group H, benzyl or naphthylmethyl and at least one instance of R is a benzyl or naphthylmethyl group.

22. A composition as recited in any previous embodiment, wherein the benzyl additive is a non-metal or metalloid containing compound of the formula ER₃ where E is an element from periodic table group VA and each instance of R is independently selected from the group H, benzyl, n-butyl, isopropyl, and at least one instance of R is a benzyl, n-butyl or isopropyl group.

23. A composition as recited in any previous embodiment, wherein the benzyl additive is a non-metal or metalloid containing compound of the formula ER₄ where E is an element from periodic table group IVA and each instance of R is independently selected from the group H, benzyl, t-butyl, n-butyl, isopropyl and at least one instance of R is a benzyl, t-butyl, n-butyl, or isopropyl group.

24. A composition as recited in any previous embodiment, wherein the benzyl additive is a non-metal or metalloid containing compound of the formula ER₂ where E is an element from periodic table group IVA and each instance of R is independently selected from the group H, benzyl, t-butyl, n-butyl, isopropyl, or other substituted aromatic and at least one instance of R is a benzyl, t-butyl, n-butyl, or isopropyl group.

25. A composition as recited in any previous embodiment, wherein the benzyl additive is a compound of the formula BiR₃ where each instance of R is independently selected from the group H, benzyl, t-butyl, n-butyl, isopropyl, and at least one instance of R is a benzyl, t-butyl, n-butyl or isopropyl group.

26. A composition as recited in any previous embodiment, wherein the benzyl additive is a compound of the formula (RE)ₓM_{y}R_{z} where R is independently selected from the group H, an araalkyl group, an araalkenyl group, an araalkynyl group, an alkyl group, an alkenyl group, an alkynyl group, E is an element from groups IIIA, IVA, VA or VIA and M is an element selected from the group of periodic table groups IA-IVA, transition metal series and lanthanide series, x is 0-6, y is 0-6 and z is 0-6.

27. A composition as recited in any previous embodiment, wherein the R group is an araalkyl group, an araalkenyl group, an araalkynyl group, an alkyl group, an alkenyl group, an alkynyl group containing an element from periodic table groups IIIA-VIIA.

28. A method for synthesizing silicon thin films, comprising: combining a liquid silane and at least one benzyl additive to form a precursor ink; depositing the precursor ink on a substrate to form a film; heating the deposited film; and irradiating the heated film with high intensity light.

29. A method as recited in any previous embodiment, the precursor ink further comprising: a solvent selected from the group of solvents consisting of toluene, xylene, cyclooctane, 1,2,4-trichlorobenzene, dichloromethane and mixtures thereof.

30. A method as recited in any previous embodiment, wherein the deposited film is heated to temperatures from 300° C. to 700° C. to produce amorphous silicon-containing materials.

31. A method as recited in any previous embodiment, wherein the high intensity light is selected from the group consisting of ultraviolet, infrared, and laser light sources.

32. A method as recited in any previous embodiment, wherein the liquid silane is a silane selected from the group of silanes of the formula SiₙH₂ₙ and SiₙH₂ₙ₊₂.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE 1
Electrical Properties Of Degenerately
Doped Si Thin Films Using Spincoating

| | Post-deposition | Thickness | |
|---|---|---|---|
| Additive | Treatment | (nm) | Resistivity(Ω · cm) |
| PBn₃ | 400° C., 550° C., laser | 50 | 3.3 × 10⁻² |
| PBn₃ | Preheated 400° C., | 25 | 3.6 × 10⁻³ |
| | 550° C., laser | | |
| SbBn₃ | 400° C. | ~100 | 4.8 × 10⁵ |
| SbBn₃ | 400° C., 800° C. | ~100 | 1.0 × 10⁸ |
| SbBn₃ | 400° C., 550° C., laser | ~100 | 3.3 × 10⁻² |
| BBn₃ | 400° C., laser | ~100 | 1.1 × 10⁻² |

TABLE 2
Electrical Properties Of Degenerately
Doped Si Thin Films Using AA-APCVD

| | | Substrate | Resistivity (Ω · cm) | |
|---|---|---|---|---|
| | | Temp | As | Laser |
| Type | Additive | (° C.) | deposited | Annealed |
| p | BBn₃ (9.6 at. %) | 450 | 2.07 × 10⁶ | 9.84 |
| n | PBn₃ (1 at. %) | 450 | 6.4 × 10⁶ | 1.65 |
| n | PBn₃ (1 at. %) | 500 | 5.8 × 10⁴ | 1.41 × 10⁻¹ |
| n | AsBn₃ (1 at. %) | 450 | — | 6.7 × 10⁻² |
| n | AsBn₃ (1 at. %) | 500 | — | 3.0 × 10⁻² |
| n | SbBn₃ (1 at. %) | 450 | — | 1.2 × 10⁻² |
| n | SbBn₃ (1 at. %) | 500 | — | 1.6 × 10⁻¹ |

What is claimed is:

1. A precursor composition for synthesizing silicon thin films and structures with embedded heteroatom(s), comprising:
(a) a liquid silane; and
(b) at least one benzyl additive with one or more heteroatoms.

2. A composition as recited in claim 1, wherein said additive is selected from the group of additives consisting of BBn₃, PBn₃, AsBn₃, SbBn₃, BiBn₃, ZrBn₄, SnBn₄, Bi(SBn)₃, Pb(SBn)₂, and (Bn₂SnS)₃ compounds where Bn=PhCH₂.

3. A composition as recited in claim 1, wherein said benzyl additive is a compound of the formula M⁽ⁿ⁾R_{z} where n is the oxidation state of the metal M, z is equal to n, and R is at least one organic group.

4. A composition as recited in claim 3, wherein said R group is an araalkyl group in which there is a methylene linkage to the metal M.

5. A composition as recited in claim 3, wherein said R group is selected from the group: a linear, branched, or cyclic saturated alkyl group; a linear, branched, or cyclic unsaturated alkenyl group; an alkynyl group an aryl group or a hydrogen atom.

6. A composition as recited in claim 1, wherein said benzyl additive is a non-metal or metalloid containing compound of the formula ER₃ where E is an element from periodic table group IIIA and each instance of R is independently selected from the group H, benzyl, n-butyl, t-butyl, isopropyl substituted aromatic hydrocarbon and at least one instance of R is a benzyl, n-butyl, t-butyl, isopropyl group.

7. A composition as recited in claim 1, wherein said benzyl additive is a non-metal or metalloid containing compound of the formula ER₃ where E is an element from periodic table group IIIA and each instance of R is independently selected from the group H, benzyl or naphthylmethyl and at least one instance of R is a benzyl or naphthylmethyl group.

8. A composition as recited in claim 1, wherein said benzyl additive is a non-metal or metalloid containing compound of the formula ER₃ where E is an element from periodic table group VA and each instance of R is independently selected from the group H, benzyl, n-butyl, isopropyl, and at least one instance of R is a benzyl, n-butyl or isopropyl group.

9. A composition as recited in claim 1, wherein said benzyl additive is a non-metal or metalloid containing compound of the formula ER₄ where E is an element from periodic table group IVA and each instance of R is independently selected from the group H, benzyl, t-butyl, n-butyl, isopropyl and at least one instance of R is a benzyl, t-butyl, n-butyl, or isopropyl group.

10. A composition as recited in claim 1, wherein said benzyl additive is a non-metal or metalloid containing compound of the formula ER₂ where E is an element from periodic table group IVA and each instance of R is independently selected from the group H, benzyl, t-butyl, n-butyl, isopropyl, or other substituted aromatic and at least one instance of R is a benzyl, t-butyl, n-butyl, or isopropyl group.

11. A composition as recited in claim 1, wherein said benzyl additive is a compound of the formula BiR₃ where each instance of R is independently selected from the group H, benzyl, t-butyl, n-butyl, isopropyl, and at least one instance of R is a benzyl, t-butyl, n-butyl or isopropyl group.

12. A composition as recited in claim 1, wherein said benzyl additive is a compound of the formula (RE)ₓM_{y}R_{z} where R is independently selected from the group H, an araalkyl group, an araalkenyl group, an araalkynyl group, an alkyl group, an alkenyl group, an alkynyl group, E is an element from groups IIIA, IVA, VA or VIA and M is an element selected from the group of periodic table groups IA-IVA, transition metal series and lanthanide series, x is 0-6, y is 0-6 and z is 0-6.

13. A composition as recited in claim 12, wherein said R group is an araalkyl group, an araalkenyl group, an araalkynyl group, an alkyl group, an alkenyl group, an alkynyl group containing an element from periodic table groups IIIA-VIIA.

14. A precursor composition for synthesizing silicon thin films and structures with embedded heteroatom(s), comprising:
(a) a liquid silane of the formula SiₙH₂ₙ or SiₙH₂ₙ₊₂ where n is from 3 to 20;
(b) at least one benzyl additive; and
(c) at least one solvent.

15. A composition as recited in claim 14, wherein said solvent is selected from the group of solvents consisting of toluene, xylene, cyclooctane, 1,2,4-trichlorobenzene, dichloromethane and mixtures thereof.

16. A method for synthesizing silicon thin films, comprising:
combining a liquid silane and at least one benzyl additive to form a precursor ink;
depositing the precursor ink on a substrate to form a film;
heating the deposited film; and
irradiating the heated film with high intensity light.

17. A method as recited in claim 16, said precursor ink further comprising:
a solvent selected from the group of solvents consisting of toluene, xylene, cyclooctane, 1,2,4-trichlorobenzene, dichloromethane and mixtures thereof.

18. A method as recited in claim 16, wherein the deposited film is heated to temperatures from 300° C. to 700° C. to produce amorphous silicon-containing materials.

19. A method as recited in claim 16, wherein said high intensity light is selected from the group consisting of ultraviolet, infrared, and laser light sources.

20. A method as recited in claim 16, wherein said liquid silane is a silane selected from the group of silanes of the formula SiₙH₂ₙ and SiₙH₂ₙ₊₂.
